(19) United States
(12) Patent Application Publication
(10) Pub. No.: US 2026/0076064 A1
(43) Pub. Date: Mar. 12, 2026

(54) DISPLAY DEVICE AND ELECTRONIC DEVICE INCLUDING THE SAME

(71) Applicant: Samsung Display Co., LTD., Yongin-si (KR)

(72) Inventors: Joo Young PARK, Yongin-si (KR); Jae Hyun CHAE, Yongin-si (KR); Kwang Wook CHOI, Yongin-si (KR)

(21) Appl. No.: 19/228,513

(22) Filed: Jun. 4, 2025

(30) Foreign Application Priority Data
Sep. 9, 2024 (KR) 10-2024-0122558
Jan. 7, 2025 (KR) 10-2025-0001918

(51) Int. Cl. H10K 59/80

(52) U.S. Cl. CPC H10K 59/871

(57) ABSTRACT

A display device includes a display panel including a substrate and a display unit, a circuit board connected to the substrate, a reinforcement member disposed on the substrate and extending from the circuit board toward the display unit, a protective member disposed on the substrate and extending from the display unit toward the circuit board to contact the reinforcement member, and a protective film disposed to cover the reinforcement member and in which a removal area exposing a portion of the reinforcement member is formed, wherein the removal area is defined next to (near) a contact surface in which reinforcement member and the protective member contact each other.

This application claims priority to Korean Patent Application No. 10-2024-0122558, filed on Sep. 9, 2024, and Korean Patent Application No. 10-2025-0001918, filed on Jan. 7, 2025, and all the benefits accruing therefrom under 35 U.S.C. § 119, the content of which in their entirety is herein incorporated by reference.

### BACKGROUND

### 1. Field

The disclosure relates to a play device and an electronic device including the same.

### 2. Description of the Related Art

Typically, electronic devices such as a smart phone, a tablet personal computer (“PC”), a digital camera, a laptop computer, a navigation device and a smart television (“TV”) include an organic light-emitting display device for displaying images.

Organic light-emitting display devices have advantages such as good luminance, relatively low driving voltage, relatively fast response speed and a wide range of color reproduction, and accordingly are being employed by a variety of devices including smart phones. An organic light-emitting display device include a display panel configured of multiple pixels and a circuit unit supplying a signal to a display panel.

The display panel is configured of a signal line transmitting signals for realizing an image and a substrate on which switching elements for driving the pixels are formed.

The circuit unit is configured of a system supplying a signal and power for realizing an image, a control circuit board including a controller that converts signals supplied from the system into signals to be supplied to the display panel, and a driving circuit board processing the converted signal from the control circuit board and transmitting to the display panel.

The driving circuit board may be electrically connected to a substrate of the display panel. A reinforcement member and a protective member may be disposed on the substrate of the display panel, and a protective film for protecting the reinforcement member may be disposed on the reinforcement member.

### SUMMARY

Features of the disclosure provide a display device in which a protective film that is disposed on a reinforcement member may be easily separated from the reinforcement member, and an electronic device including the same.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a display device includes a display panel including a substrate and a display unit, a circuit board connected to the substrate, a reinforcement member disposed on the substrate and extending from the circuit board toward the display unit, a protective member disposed on the substrate and extending from the display unit toward the circuit board to contact the reinforcement member, and a protective film disposed to cover the reinforcement member and in which a removal area exposing a portion of the reinforcement member is defined. The removal area is defined next to (near) a contact surface in which reinforcement member and the protective member contact each other.

In an embodiment, the removal area is disposed on a boundary line between the reinforcement member and the substrate.

In an embodiment, the removal area is defined by a first removal surface disposed to be parallel to the boundary line, a second removal surface disposed to intersect the boundary line, and a third removal surface disposed to be spaced apart from the first removal surface so that the boundary line is disposed between the third removal surface and the first removal surface.

In an embodiment, a separation distance from the boundary line to the first removal surface is formed to be shorter than a separation distance from the boundary line to the third removal surface.

In an embodiment, a separation distance from the contact surface to the second removal surface is formed to be longer than a separation distance from the boundary line to the first removal surface.

In an embodiment, the protective film is extended to the outside of the substrate, and the third removal surface is disposed outside the substrate.

In an embodiment, the width of the reinforcement member in a first direction is formed to be smaller than the width of the substrate in the first direction, and one side and an opposite side of the reinforcement member in the first direction are disposed inside the substrate.

In an embodiment, the protective film is extended from a periphery of the one side of the reinforcement member in the first direction to the outside of the substrate, and the removal area is defined on the boundary line between the opposite side of the reinforcement member and the substrate.

In an embodiment, one side of the protective film in the first direction is spaced apart from a boundary line between the one side of the reinforcement member and the substrate.

In an embodiment, the protective film is extended in the first direction so that the one side and an opposite side of the protective film in the first direction are disposed outside the substrate, the removal area is provided in plural so that a plurality of removal areas is provided, the plurality of removal areas include a first removal area and a second removal area, the first removal area is defined on the boundary line between the opposite side of the reinforcement member and the substrate, and the second removal area is defined on the boundary line between the one side of the reinforcement member and the substrate.

In an embodiment, the first removal area is defined by a first-first removal surface disposed to be parallel to the boundary line between the opposite side of the reinforcement member and the substrate, a first-second removal surface disposed to intersect the boundary line between the opposite side of the reinforcement member and the substrate, and a first-third removal surface disposed to be spaced apart from the first-first removal surface so that the boundary line between the opposite side of the reinforcement member and the substrate is disposed between the first-third removal surface and the first-first removal surface.

In an embodiment, a separation distance from the boundary line between the opposite side of the reinforcement member and the substrate to the first-first removal surface is formed to be shorter than a separation distance from the boundary line between the opposite side of the reinforcement member and the substrate to the first-third removal surface.

In an embodiment, a separation distance from the contact surface to the first-second removal surface is formed to be longer than a separation distance from the boundary line between the opposite side of the reinforcement member and the substrate to the first-first removal surface.

In an embodiment, the first-third removal surface is disposed outside the substrate.

In an embodiment, the second removal area is defined by a second-first removal surface disposed to be parallel to the boundary line between the one side of the reinforcement member and the substrate, a second-second removal surface disposed to intersect the boundary line between the one side of the reinforcement member and the substrate, and a second-third removal surface disposed to be spaced apart from the second-first removal surface so that the boundary line between the one side of the reinforcement member and the substrate is disposed between the second-third removal surface and the second-first removal surface.

In an embodiment, a separation distance from the boundary line between the one side of the reinforcement member and the substrate to the second-first removal surface is formed to be shorter than a separation distance from the boundary line between the one side of the reinforcement member and the substrate to the second-third removal surface.

In an embodiment, a separation distance from the contact surface to the second-second removal surface is formed to be longer than a separation distance between the one side of the reinforcement member and the substrate to the second-first removal surface.

In an embodiment, the second-third removal surface is disposed outside the substrate.

In an embodiment of the disclosure, an electronic device includes a display panel including a substrate and a display unit, a circuit board connected to the substrate, a reinforcement member disposed on the substrate and extending from the circuit board toward the display unit, a protective member disposed on the substrate and extending from the display unit toward the circuit board to contact the reinforcement member, and a protective film disposed to cover the reinforcement member and in which at least one or more removal area exposing a portion of the reinforcement member is formed, wherein the at least one or more removal area is defined at a periphery of a contact area in which the reinforcement member and the protective member contact each other.

In an embodiment, the at least one or more removal area is disposed on a boundary line between the reinforcement member and the substrate.

In an embodiment of the disclosure, by forming a removal area in which a protective film is formed to be disposed on a boundary line between the reinforcement member and the substrate, it is possible to for the protective film to be easily separated from the reinforcement member even when the protective member penetrates into the boundary line between the reinforcement member and the substrate.

The effects in the embodiments of the disclosure are not limited to those mentioned above and more various effects are included in the following description of the disclosure.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view of an embodiment of an electronic device according to the disclosure;

FIG. 2 is a plan view of an embodiment of a display device according to the disclosure;

FIG. 3 is a cross-sectional view cut along line A-A′ of FIG. 2;

FIG. 4 is a cross-sectional view schematically illustrating a display panel of FIG. 3;

FIG. 5 is a plan view illustrating a state in which a protective film of a first embodiment is disposed in FIG. 2;

FIG. 6 is an enlarged diagram of portion B of FIG. 5;

FIG. 7 is an enlarged diagram of portion C of FIG. 5;

FIG. 8 is a plan view illustrating a state in which a protective film of a second embodiment is disposed in FIG. 2;

FIG. 9 is an enlarged diagram of portion D of FIG. 8; and

FIG. 10 is an enlarged diagram of portion E of FIG. 8.

### DETAILED DESCRIPTION

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The drawing figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments may be practiced individually or in combination.

Hereinafter, embodiments of the disclosure will be described in detail with reference to the accompanying drawings.

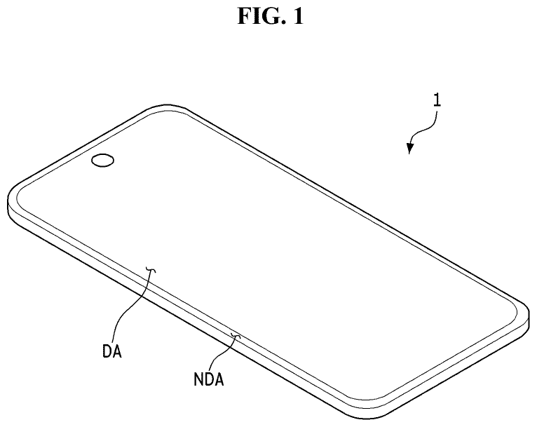

FIG. 1 is a perspective view of an embodiment of an electronic device according to the disclosure.

Referring to FIG. 1, an electronic device 1 in the embodiment of the disclosure may include a variety of electronic devices that provide a display screen. In embodiments, the electronic device 1 may include, but are not limited to, a mobile phone, a smart phone, a tablet personal computer (“PC”), a mobile communications terminal, an electronic organizer, an e-book, a personal digital assistant (“PDA”), a portable multimedia player (“PMP”), a navigation device, an ultra mobile PC (“UMPC”), a television set, a game machine, a wristwatch-type electronic device, a head-mounted display, a personal computer monitor, a laptop computer, a vehicle instrument cluster, a digital camera, a camcorder, an outdoor billboard, an electronic billboard, various medical apparatuses, various inspection devices, various home appliances including a display area such as a refrigerator and a laundry machine, Internet of things (“IoT”) devices, etc.

The electronic device 1 may include a display area DA and a non-display area NDA. The shape of the display area DA may follow the shape of the electronic device 1 when viewed from the top. In an embodiment, when the electronic device 1 has a quadrangular shape, e.g., rectangular shape when viewed from the top, the display area DA may also have a quadrangular shape, e.g., rectangular shape when viewed from the top, for example.

The display area DA may include a plurality of pixels to display images. The non-display area NDA may display no image because it does not include the pixels. The non-display area NDA may be disposed around the display area DA. The non-display area NDA may surround the display area DA, but the embodiments of the disclosure are not limited thereto. The display area DA may be partially surrounded by the non-display area NDA.

The electronic device 1 in an embodiment of the disclosure may include a display device 10.

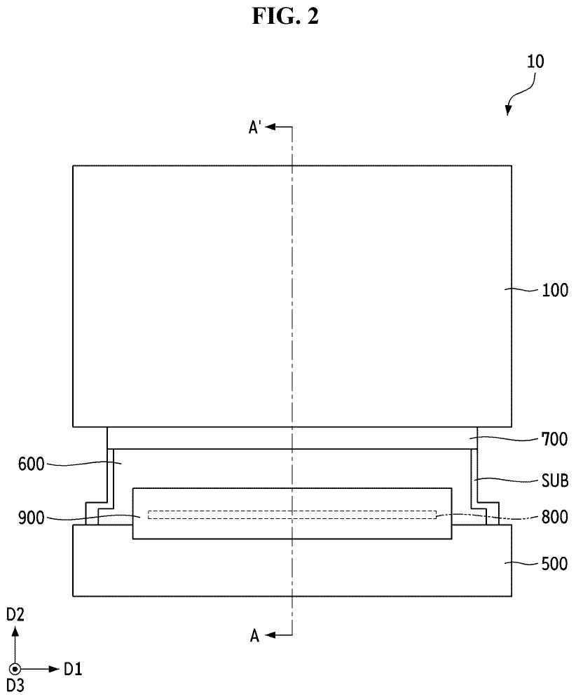

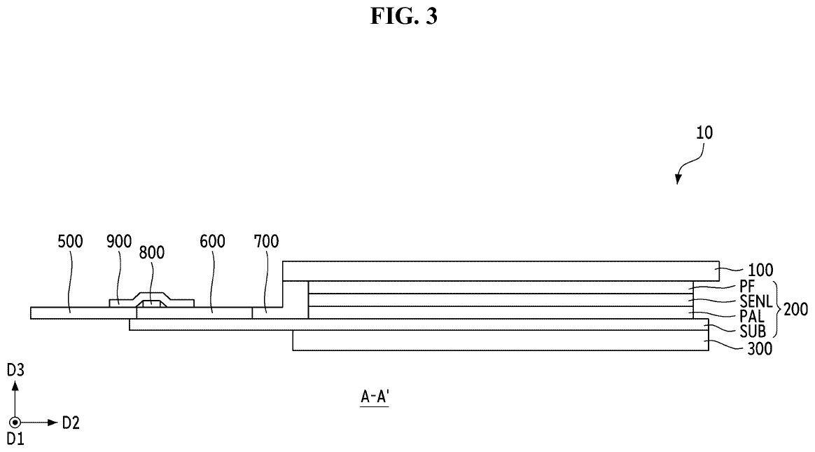

FIG. 2 is a plan view of an embodiment of a display device according to the disclosure. FIG. 3 is a cross-sectional view cut along line A-A′ of FIG. 2.

The display device 10 in an embodiment of the disclosure is for displaying moving images or still images. The display device 10 may be used as the display screen of portable electronic devices such as a mobile phone, a smart phone, a tablet PC, a smart watch, a watch phone, a mobile communications terminal, an electronic notebook, an electronic book, a PMP, a navigation device and a UMPC, as well as the display screen of various products such as a television, a notebook, a monitor, a billboard and the IoT. In an alternative embodiment, the display device 10 may be used as a display screen applied to the center fascia of a vehicle.

The display device 10 may be a light-emitting display device such as an organic light-emitting display device using organic light-emitting diodes (“OLED”), a quantum-dot light-emitting display device including quantum-dot light-emitting layer, an inorganic light-emitting display device including an inorganic semiconductor, and a micro light-emitting display device using micro light-emitting diodes (“LED”). In the following description, an organic light-emitting display device is described in an embodiment of the display device 10. It is, however, to be understood that the disclosure is not limited thereto.

A first direction D1 may be parallel to one side of the display device 10, e.g., the horizontal direction of the display device 10 when viewed from the top. A second direction D2 may be parallel to an opposite side contacting the one side of the display device 10, e.g., the vertical direction of the display device 10 when viewed from the top. A third direction D3 may refer to the thickness direction of the display device 10.

The display device 10 may have a square shape, such as a rectangle when viewed from the top. In an embodiment, the display device 10 may have a shape of a rectangle having longer sides in the first direction D1 and shorter sides in the second direction D2 when viewed from the top, for example. The corners where the longer sides in the first direction D1 meet the shorter sides in the second direction D2 may be rounded with a predetermined curvature or may be a right angle. The shape of the display device 10 when viewed from the top is not limited to a quadrangular shape, e.g., rectangular shape but may be formed in another polygonal shape, a circular shape, or an elliptical shape.

Referring to FIGS. 2 and 3, the display device 10 in an embodiment of the disclosure may include a cover window 100, a display panel 200, a panel bottom member 300, a circuit board 500, a reinforcement member 600, a protective member 700, a driving circuit 800, and a cover member 900.

The cover window 100 may include a material with relatively high light transmittance. The cover window 100 may include a polymer resin such as polyimide or glass. The cover window 100 may be attached onto a polarizing film PF of the display panel 200 by an adhesive member such as an optically clear adhesive (“OCA”) film.

The display panel 200 may be disposed under the cover window 100. The display panel 200 may have a quadrangular shape, e.g., rectangular shape having longer sides in the first direction D1 and shorter sides in the second direction D2 when viewed from the top. In the display panel 200, the corners where the longer sides in the first direction D1 meet the shorter sides in the second direction D2 may be a right angle or may be rounded with a predetermined curvature. The display panel 200 may have a quadrangular shape other than a rectangle, a polygonal shape other than a quadrangular shape, a circular shape, an elliptical shape, or an irregular shape when viewed from the top.

The display panel 200 may include a display area where a plurality of emission areas that emits light is arranged, and a non-display area disposed around the display area. The non-display area may surround the display area. A plurality of display pads may be disposed in the non-display area at one edge of the display panel 200.

The display panel 200 may include a substrate SUB, a display unit PAL, a sensor unit SENL and a polarizing film PF.

The substrate SUB may include or consist of an insulating material such as glass, quartz and a polymer resin. The substrate SUB may be a rigid substrate or a flexible substrate that may be bent, folded, rolled, and so on. The substrate SUB may be extended in one direction further than a display unit PAL, a sensor unit SENL, and a polarizing film PF disposed on the top portion.

The display unit PAL may be disposed on the substrate SUB. The display unit PAL may be a layer including a plurality of emission areas that emit light. The display unit PAL may include a buffer film, a thin-film transistor layer on which thin-film transistors are disposed, a light-emitting element layer that emits light, and an encapsulating layer for encapsulating the light-emitting element layer.

The sensor unit SENL may be disposed on the display unit PAL. The sensor unit SENL may include sensor electrodes and may sense whether there is a user's touch.

The polarizing film PF may be disposed on the sensor unit SENL. The polarizing film PF may prevent the deterioration of image visibility of the display panel 200 due to reflection of external light. The polarizing film PF may include a linear polarizer and a phase retardation film such as a l/4 (quarter-wave) plate. The phase retardation film may be disposed on the sensor unit SENL, and the linear polarizer may be disposed on the phase retardation film. The cover window 100 may be disposed on the polarizing film PF.

The panel bottom member 300 may be disposed under the substrate SUB. The panel bottom member 300 may be attached to the lower surface of the substrate SUB by an adhesive layer (not illustrated). The adhesive layer (not illustrated) may be a pressure-sensitive adhesive (“PSA”). The panel bottom member 300 may include at least one of: a light-absorbing member for absorbing light incident from outside, a buffer member for absorbing external impact, and a heat dissipating member for efficiently discharging heat from the display panel 200.

The light-absorbing member may be disposed under the substrate SUB. The light-absorbing member blocks the transmission of light to prevent the elements disposed thereunder from being seen from above the display panel 200, such as the circuit board 500. The light-absorbing member may include a light-absorbing material such as a black pigment and a black dye.

The buffer member may be disposed under the light-absorbing member. The buffer member absorbs an external impact to prevent the display panel 200 from being damaged. The buffer member may be made up of a single layer or multiple layers. In an embodiment, the buffer member may include or consist of a polymer resin such as polyurethane, polycarbonate, polypropylene and polyethylene, or may include or consist of a material having elasticity such as a rubber and a sponge obtained by foaming a urethane-based material or an acrylic-based material, for example.

The heat dissipating member may be disposed under the buffer member. The heat dissipating member may include a first heat dissipation layer including graphite or carbon nanotubes, and a second heat dissipation layer including or consisting of a thin metal film such as copper, nickel, ferrite and silver, which may block electromagnetic waves and have relatively high thermal conductivity.

The circuit board 500 may be overlapped with the panel bottom member 300 when the substrate SUB is bent. The circuit board 500 be a flexible printed circuit board (“FPCB”) that may be bent, a rigid printed circuit board (“PCB”) that is rigid and not bendable, or a hybrid printed circuit board including a rigid printed circuit board and a flexible printed circuit board.

The circuit board 500 may process the converted signal in a control circuit board (not illustrated) and transmit to the display panel 200. The circuit board 500 may be electrically connected to the substrate SUB.

The reinforcement member 600 may be disposed on the substrate SUB and extend from the circuit board 500 toward the display unit PAL on the substrate SUB. In an embodiment, the reinforcement member 600 may be extended to the first direction D1 and the second direction D2 on the substrate SUB, for example. One side (lower side in FIG. 2) of the reinforcement member 600 in the second direction D2 may contact the circuit board 500, and an opposite side (upper side in FIG. 2) of the reinforcement member 600 in the second direction D2 may extend along the second direction D2 toward the display unit PAL.

The width of the reinforcement member 600 in the first direction D1 may be smaller than the width of the substrate SUB in the first direction D1. In some embodiments, since the reinforcement member 600 is formed to have a smaller width in the first direction D1 than a width of the substrate SUB in the first direction D1, one side (left side of FIG. 2) and an opposite side (right side in FIG. 2), opposite to each other in first direction D1, of the reinforcement member 600 may be disposed inside the substrate SUB. The boundary line between the reinforcement member 600 and the substrate SUB may be parallel in the second direction D2.

The reinforcement member 600 may be overlapped with the driving circuit 800 and may prevent stress that occurs by the substrate SUB bending to be delivered to the driving circuit 800. The reinforcement member 600 may include a stainless steel.

The protective member 700 may be disposed on the substrate SUB and extend from the display unit PAL, the sensor unit SENL, and the polarizing film PF toward the circuit board 500 and contact the reinforcement member 600. In an embodiment, the protective member 700 may extend in the first direction D1 and the second direction D2 on the substrate SUB, for example. An opposite side (upper side in FIG. 2) of the protective member 700 in the second direction D2 may contact the display unit PAL, the sensor unit SENL, and the polarizing film PF, and one side (lower side in FIG. 2) of the protective member 700 in the second direction D2 may be extended along the second direction D2 toward the circuit board 500 and contact the reinforcement member 600.

The width of the protective member 700 in the first direction D1 may be formed to correspond to the width of the substrate SUB in the first direction D1. The contact surface between the protective member 700 and the reinforcement member 600 may be parallel in the first direction D1. In some embodiments, the contact surface between the protective member 700 and the reinforcement member 600 may be formed to intersect in the second direction D2.

The protective member 700 may be a bending protective layer. The protective member 700 may be bent together with the substrate SUB when the substrate SUB is bent. The protective member 700 may prevent the bending portion of the substrate from being damaged by external impact or external foreign substances from entering. The protective member 700 shown in the drawing is merely one of embodiments, and the shape of the protective member 700 may be changed according to needs.

The protective member 700 may include a plastic film as a base layer. The protective member 700 may include a plastic film such as polyethersulphone (“PES”), polyacrylate (“PA”), polyetherimide (“PEI”), polyethylene naphthalate (“PEN”), polyethylene terepthalate (“PET”), polyphenylene sulfide (“PPS”), polyallylate, polyimide (“PI”), polycarbonate (“PC”), polyarylene ethersulfone, and any one selected from a group consisting of combinations thereof. The materials constituting the protective member 700 are not limited to plastic resins and may include organic/inorganic composite materials. The protective member 700 may include a porous organic layer and an inorganic material filled in pores of the organic layer. The protective member 700 may include a single layer or a multi-layer structure.

The driving circuit 800 may receive control signals and power voltages through the circuit board 500 and generate and output signals and voltages for driving the display panel 200. The driving circuit 800 may be formed as an integrated circuit (“IC”) and electrically connected to the substrate SUB and a circuit board 500. The driving circuit 800 may be disposed to overlap the reinforcement member 600 on the reinforcement member 600.

The cover member 900 may be disposed to cover the driving circuit 800 and a portion of each of the circuit board 500 and the reinforcement member 600. In an embodiment, a portion of the cover member 900 may be disposed on the reinforcement member 600, and a remaining (the other) portion of the cover member 900 may be disposed on the circuit board 500 and be disposed to cover the entirety of the driving circuit 800 disposed on the reinforcement member 600, for example. The cover member 900 may protect the driving circuit 800 from external impact.

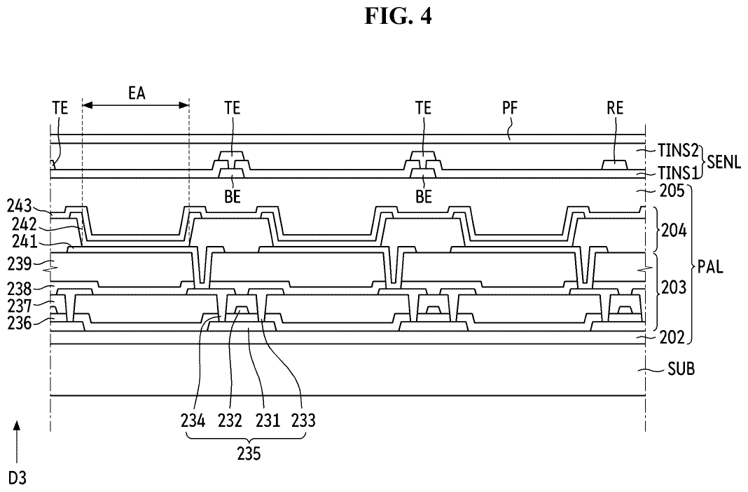

FIG. 4 is a cross-sectional view schematically illustrating a display panel of FIG. 3.

Referring to FIG. 4, the display unit PAL may include a buffer film 202, a thin-film transistor layer 203, a light-emitting element layer 204, and an encapsulation layer 205.

The buffer film 202 may be formed on the substrate SUB. The buffer film 202 may be formed on the substrate SUB to protect thin-film transistors 235 and light-emitting elements from moisture permeating through the substrate SUB which is susceptible to moisture permeation. The buffer film 202 may include or consist of multiple inorganic layers alternately stacked. In an embodiment, the buffer film 202 may include or consist of multiple films in which one or more inorganic films of a silicon oxide film (SiOx), a silicon nitride film (SiNx), and a silicon oxynitride film SiON are alternately stacked, for example. The buffer film 202 may be omitted.

The thin-film transistor layer 203 may be disposed on the buffer film 202. The thin-film transistor layer 203 includes the thin-film transistors 235, a gate insulating film 236, an inter-insulating film 237, a protective film 238, and an organic film 239.

Each of the thin-film transistors 235 includes an active layer 231, a gate electrode 232, a source electrode 233, and a drain electrode 234. In FIG. 4, it is exemplified that the thin-film transistor 235 is formed in a top gate manner in which the gate electrode 232 is disposed on top of the active layer 231, but it should be noted that the disclosure is not limited thereto. That is, the thin-film transistors 235 may be formed in a bottom gate manner in which the gate electrode 232 is disposed on the bottom of the active layer 231, or a double gate manner in which the gate electrode 232 is disposed on both of the top and bottom of the active layer 231.

The active layer 231 is formed on the buffer film 202. The active layer 231 may include or consist of a silicon-based semiconductor material or an oxide-based semiconductor material. In an embodiment, the active layer 231 may include or consist of a poly silicon, an amorphous silicon, or an oxide semiconductor, for example. A light-blocking layer for blocking external light incident on the active layer 231 may be formed between the buffer film 202 and the active layer 231.

The gate insulating film 236 may be formed on the active layer 231. The gate insulating film 236 may include or consist of an inorganic film, e.g., a silicon oxide film (SiOx), a silicon nitride film (SiNx), or a multiple film thereof.

The gate electrode 232 may be formed on the gate insulating film 236. The gate electrode 232 and a gate line may be formed as a single layer or multiple layers including or consisting of any one of molybdenum (Mo), aluminum (Al), chromium (Cr), gold (Au), titanium (Ti), nickel (Ni), neodymium (Nd) and copper (Cu) or any alloys thereof.

The inter-insulating film 237 may be formed on the gate electrode 232 and the gate line. The inter-insulating film 237 may include or consist of an inorganic film, e.g., a silicon oxide film (SiOx), a silicon nitride film (SiNx), or a multiple film thereof.

The source electrode 233 and the drain electrode 234 may be formed on the inter-insulating film 237. Each of the source electrode 233 and the drain electrode 234 may be connected to the active layer 231 through a contact hole penetrating the gate insulating film 236 and the inter-insulating film 237. The source electrode 233 and the drain electrode 234 may be formed as a single layer or multiple layers including or consisting of any one of molybdenum (Mo), aluminum (Al), chromium (Cr), gold (Au), titanium (Ti), nickel (Ni), neodymium (Nd) and copper (Cu) or any alloys thereof.

The protective film 238 for insulating the thin-film transistors 235 may be formed on the source electrode 233 and the drain electrode 234. The protective film 238 may include or consist of an inorganic film, e.g., a silicon oxide film (SiOx), a silicon nitride film (SiNx), or a multiple film thereof.

The organic film 239 for planarizing a step due to the thin-film transistor 235 may be formed on the protective film 238. The organic film 239 may include or consist of an organic film such as acryl resin, epoxy resin, phenolic resin, polyamide resin, polyimide resin or the like.

The light-emitting element layer 204 is formed on the thin-film transistor layer 203. The light-emitting element layer 204 includes the light-emitting elements and a bank.

The light-emitting elements and the bank are formed on the organic film 239. The light-emitting element is exemplified as an organic light-emitting element including an anode electrode 241, light-emitting layers 242, and a cathode electrode 243.

The anode electrode 241 may be formed on the organic film 239. The anode electrode 241 may be connected to the source electrode 233 of the thin-film transistor 235 through a contact hole penetrating the protective film 238 and the organic film 239.

The bank may be formed to cover the edge of the anode electrode 241 on the organic film 239 to partition emission areas EA of pixels. That is, the bank serves to define the emission areas EA of pixels. Each of the pixels, in which the anode electrode 241, the light-emitting layer 242, and the cathode electrode 243 are sequentially stacked, indicates an area in which holes from the anode electrode 241 and electrons from the cathode electrode 243 are combined with each other in the light-emitting layer 242 to emit light.

The light-emitting layer 242 is formed on the anode electrode 241 and the bank. The light-emitting layer 242 may be an organic light-emitting layer. The light-emitting layer 242 may emit one of red light, green light and blue light. In an alternative embodiment, the light-emitting layer 242 may be a white light-emitting layer that emits white light. In this case, the light-emitting layer 242 may have a structure in which a red light-emitting layer, a green light-emitting layer, and a blue light-emitting layer are stacked, and may be a common layer formed commonly to the pixels. In this case, the display panel 200 may further include a separate color filter for displaying a red, green or blue color.

The light-emitting layer 242 may include a hole transporting layer, a light-emitting layer, and an electron transporting layer. In addition, the light-emitting layer 242 may be formed in a tandem structure of two or more stacks, in which case a charge generating layer may be formed between the stacks.

The cathode electrode 243 is formed on the light-emitting layer 242. The cathode electrode 243 may be formed to cover the light-emitting layer 242. The cathode electrode 243 may be a common layer formed commonly to the pixels.

In a case where the light-emitting element layer 204 is formed by a top emission method in which light is emitted upward, the anode electrode 241 may include or consist of a metal material having relatively high reflectivity to have a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO. The APC alloy is an alloy of silver (Ag), palladium (Pd) and copper (Cu). Further, the cathode electrode 243 may include or consist of a transparent conductive material (“TCO”) such as indium tin oxide (“ITO”) or indium zinc oxide (“IZO”) that may transmit light or a semi-transmissive conductive material such as magnesium (Mg), silver (Ag), or an alloy of magnesium (Mg) and silver (Ag). In a case where the cathode electrode 243 includes or consists of a semi-transmissive conductive material, the light emission efficiency may be increased due to a micro-cavity effect.

In a case where the light-emitting element layer 204 is formed by a bottom emission method in which light is emitted downward, the anode electrode 241 may include or consist of a transparent conductive material (“TCO”) such as ITO or IZO or a semi-transmissive conductive material such as magnesium (Mg), silver (Ag), or an alloy of magnesium (Mg) and silver (Ag). The cathode electrode 243 may include or consist of a metal material, having relatively high reflectivity, such as a stacked structure (Ti/Al/Ti) of aluminum (Al) and titanium (Ti), a stacked structure (ITO/Al/ITO) of Al and ITO, an APC alloy, a stacked structure (ITO/APC/ITO) of an APC alloy and ITO, or the like. In a case where the anode electrode 241 includes or consists of a semi-transmissive conductive material, the light emission efficiency may be increased due to a micro-cavity effect.

The encapsulation layer 205 is formed on the light-emitting element layer 204. The encapsulation layer 205 serves to prevent air or moisture from permeating the light-emitting layer 242 and the cathode electrode 243. To this end, the encapsulation layer 205 may further comprise at least one inorganic film. The inorganic film may include or consist of silicon nitride, aluminum nitride, zirconium nitride, titanium nitride, hafnium nitride, tantalum nitride, silicon oxide, aluminum oxide, or titanium oxide. In addition, the encapsulation layer 205 may further include at least one organic film. The inorganic film may have a thickness sufficient to prevent particles from penetrating the encapsulation layer 205 and entering the light-emitting layer 242 and the cathode electrode 243. The organic film may include any one of epoxy, acrylate, and urethane acrylate.

The sensor unit SENL may be formed on the encapsulation layer 205. In case in which the sensor unit SENL is formed directly on the encapsulation layer 205, the thickness of the display device 10 may be reduced, compared with a display device in which a separate touch panel is attached on the encapsulation layer 205.

The sensor unit SENL may include sensor electrodes for sensing a user's touch by a capacitive manner, and touch lines connecting the pads and the sensor electrodes. In an embodiment, the sensor unit SENL may sense a user's touch by self-capacitance sensing or mutual capacitance sensing, for example. In the example shown in FIG. 4, the sensor unit SENL is made up of two layers including driving electrodes TE, sensing electrodes RE and bridges BE connecting between the driving electrodes TE for mutual capacitance sensing.

The bridges BE may be formed on the encapsulation layer 205. The bridges BE may be made up of, but is not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). In an embodiment, the bridges BE may be made up of a single layer of molybdenum (Mo), titanium (Ti), copper (Cu), aluminum (Al) or ITO, for example.

A first sensing insulating film TINS1 is formed over the bridges BE. The first sensing insulating film TINS1 may include or consist of an inorganic film, e.g., a silicon nitride layer, a silicon oxynitride layer, a silicon oxide layer, a titanium oxide layer, or an aluminum oxide layer.

The driving electrodes TE and the sensing electrodes RE may be formed on the first sensing insulating film TINS1. The driving electrode TE and the sensing electrode RE may be formed as, but is not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). In an embodiment, the driving electrodes TE and the sensing electrodes RE may be made up of a single layer of molybdenum (Mo), titanium (Ti), copper (Cu), aluminum (Al) or ITO, for example.

Contact holes may be formed in the first sensing insulating film TINS1 which penetrate the first sensing insulating film TINS1 to expose the bridges BE. The driving electrodes TE may be connected to the bridges BE through the contact holes.

A second sensing insulating film TINS2 is formed over the driving electrodes TE and the sensing electrodes RE. The second sensing insulating film TINS2 may provide a flat surface over the driving electrodes TE, the sensing electrodes RE and the bridges BE which have different heights. The second sensing insulating film TINS2 may include or consist of an organic film such as an acryl resin, an epoxy resin, a phenolic resin, a polyamide resin and a polyimide resin.

The bridges BE connecting between the neighboring (adjacent) driving electrodes TE may be disposed on the encapsulation layer 205, and the driving electrodes TE and the sensing electrodes RE may be disposed on the first sensing insulating film TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The polarizing film PF may be disposed on the second sensing insulating film TINS2 and may prevent the deterioration of image visibility of the display panel 200 due to reflection of external light.

The display device 10 in an embodiment of the disclosure may further include a protective film 1000. The protective film 1000 may have a plurality of embodiments, and the plurality of embodiments of the protective film 1000 may include a first embodiment and a second embodiment.

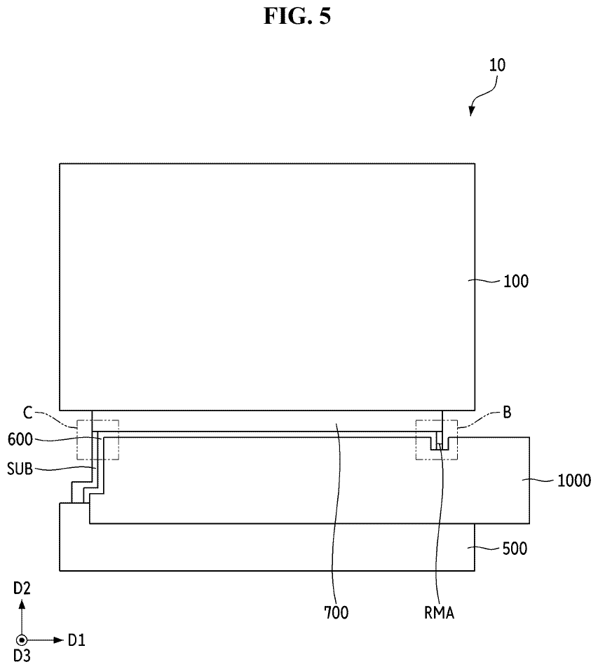

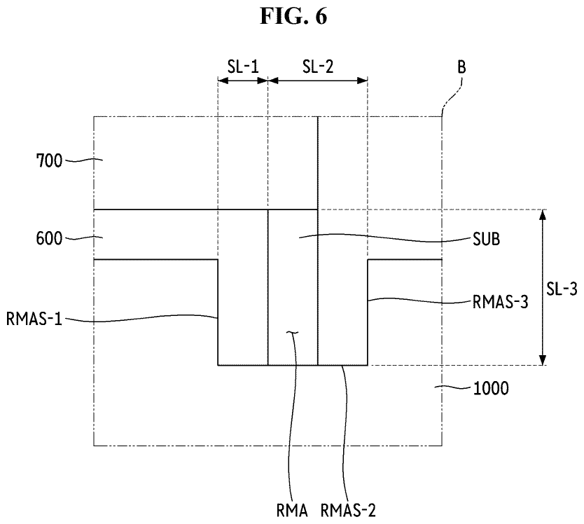

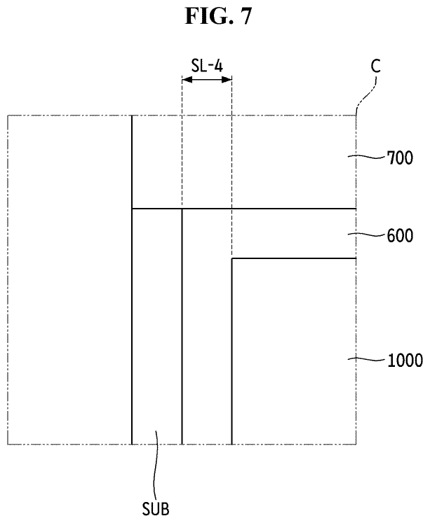

FIG. 5 is a plan view illustrating a state in which a protective film of a first embodiment is disposed in FIG. 2. FIG. 6 is an enlarged diagram of portion B of FIG. 5. FIG. 7 is an enlarged diagram of portion C of FIG. 5.

Referring to FIGS. 5 to 7, the protective film 1000 according to the first embodiment may be disposed to extend in the first direction D1 and cover the reinforcement member 600. In an embodiment, the protective film 1000 may be extended along the first direction D1 from one side (left side in FIG. 5) of the reinforcement member 600 in the first direction D1 to be extended to the outside of the substrate SUB, for example. In some embodiments, the one side (left side in FIG. 5) of the protective film 1000 in the first direction D1 may be disposed on the circuit board 500 and the reinforcement member 600, and an opposite side (right side in FIG. 5) of the protective film 1000 in the first direction D1 may be disposed outside the substrate SUB.

The one side (left side in FIG. 5) of the protective film 1000 in the first direction D1 may be spaced apart from the boundary line between an opposite side (left side in FIG. 5) of the reinforcement member 600 in the first direction D1 and the substrate SUB. In some embodiments, the one side (left side in FIG. 5) of the protective film 1000 in the first direction D1 may be spaced apart from one side (left side in FIG. 5) of the reinforcement member 600 in the first direction D1 by a separation distance SL-4. As described above, since the one side (left side in FIG. 5) of the protective film 1000 in the first direction D1 is spaced apart from the boundary line between the one side (left side in FIG. 5) of the reinforcement member 600 in the first direction D1, even when the protective member 700 penetrates the boundary line between the reinforcement member 600 and the substrate SUB, the reinforcement member 600 and the protective film 1000 do not contact each other and the protective film 1000 may be easily separated from the reinforcement member 600.

In addition, the protective film 1000 may be disposed to extend in the second direction D2 and cover the reinforcement member 600. In an embodiment, one side (lower side in FIG. 5) of the protective film 1000 in the second direction D2 may be disposed on the circuit board 500, and an opposite side (upper side in FIG. 5) of the protective film 1000 in the second direction D2 may be disposed on the reinforcement member 600, for example. In some embodiments, the protective film 1000 may be extended in the second direction D2 on the circuit board 500 and the reinforcement member 600. An opposite side (upper side of FIG. 5) of the protective film 1000 in the second direction D2 may be extended in the first direction D1 to be parallel to a contact surface between the reinforcement member 600 and the protective member 700, next to (near) the contact surface between the reinforcement member 600 and the protective member 700.

The protective film 1000 may define a removal area RMA. The removal area RMA may be an area defined as a portion of the protective film 1000 is removed. Since the removal area RMA is an area defined as a portion of the protective film 1000 is removed, a portion of the reinforcement member 600 may be exposed to the outside of the protective film 1000 through the removal area RMA. Next to (near) the contact area in which the reinforcement member 600 and the protective member 700 contact each other, the removal area RMA may be defined on the boundary line between an opposite side (right side in FIG. 5) of the reinforcement member 600 in the first direction D1 and the substrate SUB.

The removal area RMA may be defined by a first removal surface RMAS-1, a second removal surface RMAS-2, and a third removal surface RMAS-3.

The first removal surface RMAS-1 may be parallel to the boundary line between an opposite side (right side in FIG. 5) of the reinforcement member 600 in the first direction D1 and the substrate SUB. In some embodiments, the first removal surface RMAS-1 may be parallel in the second direction D2 while in a state of being spaced apart from the boundary line between an opposite side (right side in FIG. 5) of the reinforcement member 600 in the first direction D1 and the substrate SUB. The first removal surface RMAS-1 may be disposed on the reinforcement member 600.

The second removal surface RMAS-2 may be disposed to intersect the boundary line between an opposite side (right side in FIG. 5) of the reinforcement member 600 in the first direction D1 and the substrate SUB. In some embodiments, the second removal surface RMAS-2 may be extended from the first removal surface RMAS-1 in the first direction D1. The second removal surface RMAS-2 may pass through the substrate SUB on the reinforcement member 600 to be extended to the outside of the substrate SUB. The second removal surface RMAS-2 may be parallel to the contact surface between the reinforcement member 600 and the protective member 700.

The third removal surface RMAS-3 may be spaced apart from the first removal surface RMAS-1 so that the boundary line between an opposite side (right side in FIG. 5) of the reinforcement member 600 in the first direction D1 and the substrate SUB is disposed between the gap between the third removal surface RMAS-3 and the first removal surface RMAS-1. In some embodiments, the third removal surface RMAS-3 may be parallel in the second direction D2 while in a state of being spaced apart from the boundary line between an opposite side (right side in FIG. 5) of the reinforcement member 600 in the first direction D1 and the substrate SUB. The third removal surface RMAS-3 may be disposed outside of the substrate SUB.

A separation distance SL-1 from the first removal surface RMAS-1 to the boundary line between an opposite side (right side in FIG. 5) of the reinforcement member 600 in the first direction D1 and the substrate SUB may be shorter than a separation distance SL-2 from the third removal surface RMAS-3 to the boundary line between an opposite side (right side in FIG. 5) of the reinforcement member 600 in the first direction D1 and the substrate SUB. In addition, a separation distance SL-3 from the contact surface between the reinforcement member 600 and the protective member 700 to the second removal surface RMAS-2 may be longer than the separation distance SL-1 from the first removal surface RMAS-1 to the boundary line between an opposite side (right side in FIG. 5) of the reinforcement member 600 in the first direction D1 and the substrate SUB. The separation distance SL-3 from the contact surface between the reinforcement member 600 and the protective member 700 to the second removal surface RMAS-2 may be longer than a penetration length through which the protective member 700 penetrates along the boundary line between the reinforcement member 600 and the substrate SUB.

As described above, next to (near) the contact surface between the reinforcement member 600 and the protective member 700, since the boundary line between an opposite side (right side in FIG. 5) of the reinforcement member 600 in the first direction D1 and the substrate SUB is spaced apart from the protective film 1000 due to the removal area RMA, the protective member 700 and the protective film 1000 do not contact each other and the protective film 1000 may be easily separated from the reinforcement member 600 even when the protective member 700 penetrates the boundary line between the reinforcement member 600 and the substrate SUB.

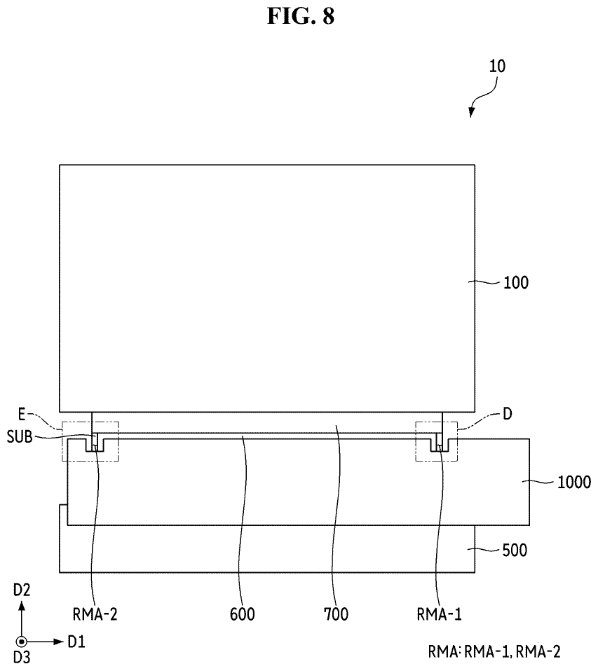

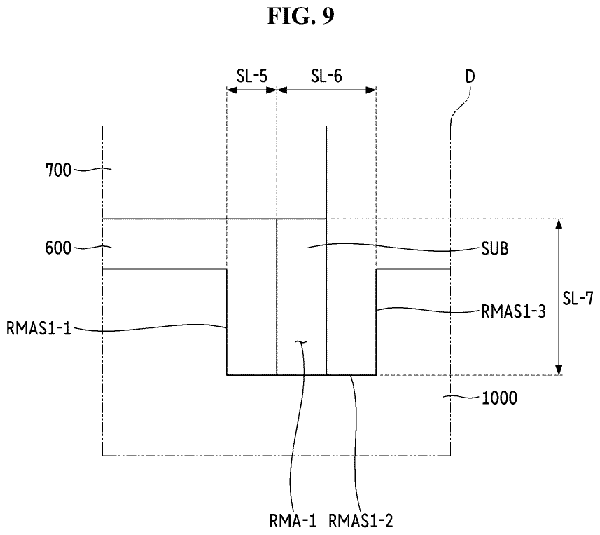

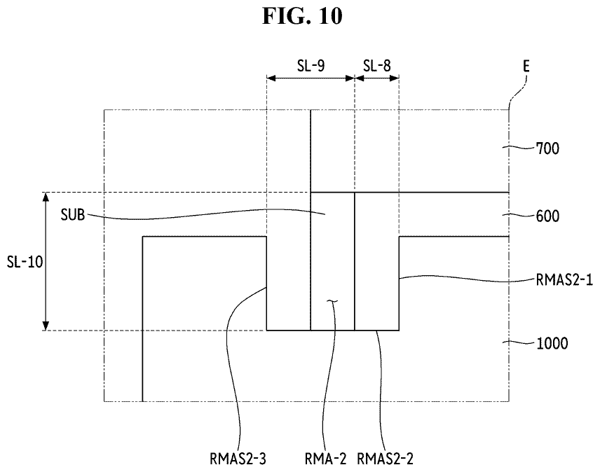

FIG. 8 is a plan view illustrating a state in which a protective film of a second embodiment is disposed in FIG. 2. FIG. 9 is an enlarged diagram of portion D of FIG. 8. FIG. 10 is an enlarged diagram of portion E of FIG. 8.

Referring to FIGS. 8 to 10, a protective film 1000 according to the second embodiment may be disposed to extend in the first direction D1 and cover the reinforcement member 600. In an embodiment, the protective film 1000 may be extended along the first direction D1 from one side (left side in FIG. 8) of the substrate SUB in the first direction D1 to be extended to the outside of an opposite side (right side in FIG. 8) of the substrate SUB in the first direction D1, for example. In some embodiments, the one side (left side in FIG. 8) of the protective film 1000 in the first direction D1 and an opposite side (right side in FIG. 8) of the protective film 1000 in the first direction D1 may be disposed outside the substrate SUB. The one side (left side in FIG. 8) of the protective film 1000 in the first direction D1 and an opposite side (right side in FIG. 8) of the protective film 1000 in the first direction D1 may be parallel to each other in the second direction D2.

In addition, the protective film 1000 may be disposed to extend in the second direction D2 and cover the reinforcement member 600. In an embodiment, one side (lower side in FIG. 8) of the protective film 1000 in the second direction D2 may be disposed on the circuit board 500, and an opposite side of the protective film 1000 in the second direction D2 (upper side in FIG. 8) may be disposed on the reinforcement member 600, for example. In some embodiments, the protective film 1000 may be extended in the second direction D2 on the circuit board 500 and the reinforcement member 600. Next to (near) the contact surface between the reinforcement member 600 and the protective member 700, an opposite side (upper side in FIG. 8) of the protective film 1000 in the second direction D2 may be extended in the first direction D1 to be parallel to the contact surface between the reinforcement member 600 and the protective member 700.

The protective film 1000 may define a removal area RMA. The removal area RMA may be an area defined as a portion of the protective film 1000 is removed. Since the removal area RMA is an area defined as a portion of the protective film 1000 is removed, a portion of the reinforcement member 600 may be exposed to the outside of the protective film 1000 through the removal area RMA. The removal area RMA may be provided in plural, and the plurality of removal areas RMA may include a first removal area RMA-1 and a second removal area RMA-2.

Next to (near) the contact surface where the reinforcement member 600 and the protective member 700 contact each other, the first removal area RMA-1 may be defined on the boundary line between an opposite side (right side in FIG. 8) of the reinforcement member 600 in the first direction D1 and the substrate SUB.

The first removal area RMA-1 may be defined by a first-first removal surface RMAS1-1, a first-second removal surface RMAS1-2, and a first-third removal surface RMAS1-3.

The first-first removal surface RMAS1-1 may be parallel to the boundary line between an opposite side (right side in FIG. 8) of the reinforcement member 600 in the first direction D1 and the substrate SUB. In some embodiments, the first-first removal surface RMAS1-1 may be parallel in the second direction D2 while in a state of being spaced apart from the boundary line between an opposite side (right side in FIG. 8) of the reinforcement member 600 in the first direction D1 and the substrate SUB. The first-first removal surface RMAS1-1 may be disposed on the reinforcement member 600.

The first-second removal surface RMAS1-2 may be disposed to intersect the boundary line between an opposite side (right side in FIG. 8) of the reinforcement member 600 in the first direction D1 and the substrate SUB. In some embodiments, the first-second removal surface RMAS1-2 may be extended from the first-first removal surface RMAS1-1 in the first direction D1. The first-second removal surface RMAS1-2 may pass through the substrate SUB on the reinforcement member 600 to be extended to the outside of the substrate SUB. The first-second removal surface RMAS1-2 may be parallel to the contact surface between the reinforcement member 600 and the protective member 700.

The first-third removal surface RMAS1-3 may be spaced apart from the first-first removal surface RMAS1-1 so that the boundary line between an opposite side (right side in FIG. 8) of the reinforcement member 600 in the first direction D1 and the substrate SUB is disposed between the gap between the first-third removal surface RMAS1-3 and the first-first removal surface RMAS1-1. In some embodiments, the first-third removal surface RMAS1-3 may be parallel in the second direction D2 while in a state of being spaced apart from the boundary line between an opposite side (right side in FIG. 8) of the reinforcement member 600 in the first direction D1 and the substrate SUB. The first-third removal surface RMAS1-3 may be disposed outside of the substrate SUB.

A separation distance SL-5 from the first-first removal surface RMAS1-1 to the boundary line between an opposite side (right side in FIG. 8) of the reinforcement member 600 in the first direction D1 and the substrate SUB may be shorter than a separation distance SL-6 from the first-third removal surface RMAS1-3 to the boundary line between an opposite side (right side in FIG. 8) of the reinforcement member 600 in the first direction D1 and the substrate SUB. In addition, a separation distance SL-7 from the contact surface between the reinforcement member 600 and the protective member 700 to the first-second removal surface RMAS1-2 may be longer than the separation distance SL-5 from the first-first removal surface RMAS1-1 to the boundary line between an opposite side (right side in FIG. 8) of the reinforcement member 600 in the first direction D1 and the substrate SUB. The separation distance SL-7 from the contact surface between the reinforcement member 600 and the protective member 700 to the first-second removal surface RMAS1-2 may be longer than a penetration length through which the protective member 700 penetrates along the boundary line between the reinforcement member 600 and the substrate SUB.

As described above, next to (near) the contact surface between the reinforcement member 600 and the protective member 700, since the boundary line between an opposite side (right side in FIG. 8) of the reinforcement member 600 in the first direction D1 and the substrate SUB is spaced apart from the protective film 1000 due to the first removal area RMA-1, the protective member 700 and the protective film 1000 do not contact each other and the protective film 1000 may be easily separated from the reinforcement member 600 even when the protective member 700 penetrates the boundary line between the reinforcement member 600 and the substrate SUB.

Next to (near) the contact surface where the reinforcement member 600 and the protective member 700 contact each other, the second removal area RMA-2 may be defined on the boundary line between one side (left side in FIG. 8) of the reinforcement member 600 in the first direction D1 and the substrate SUB.

The second removal area RMA-2 may be defined by a second-first removal surface RMAS2-1, a second-second removal surface RMAS2-2, and a second-third removal surface RMAS2-3.

The second-first removal surface RMAS2-1 may be parallel to the boundary line between the one side (left side in FIG. 8) of the reinforcement member 600 in the first direction D1 and the substrate SUB. In some embodiments, the second-first removal surface RMAS2-1 may be parallel in the second direction D2 while in a state of being spaced apart from the boundary line between the one side (left side in FIG. 8) of the reinforcement member 600 in the first direction D1 and the substrate SUB. The second-first removal surface RMAS2-1 may be disposed on the reinforcement member 600.

The second-second removal surface RMAS2-2 may be disposed to intersect the boundary line between the one side (left side in FIG. 8) of the reinforcement member 600 in the first direction D1 and the substrate SUB. In some embodiments, the second-second removal surface RMAS2-2 may be extended from the second-first removal surface RMAS2-1 in the first direction D1. The second-second removal surface RMAS2-2 may pass through the substrate SUB on the reinforcement member 600 to be extended to the outside of the substrate SUB. The second-second removal surface RMAS2-2 may be parallel to the contact surface between the reinforcement member 600 and the protective member 700.

The second-third removal surface RMAS2-3 may be spaced apart from the second-first removal surface RMAS2-1 so that the boundary line between the one side (left side in FIG. 8) of the reinforcement member 600 in the first direction D1 and the substrate SUB is disposed between the gap between the second-third removal surface RMAS2-3 and the second-first removal surface RMAS2-1. In some embodiments, the second-third removal surface RMAS2-3 may be parallel in the second direction D2 while in a state of being spaced apart from the boundary line between the one side (left side in FIG. 8) of the reinforcement member 600 in the first direction D1 and the substrate SUB. The second-third removal surface RMAS2-3 may be disposed outside of the substrate SUB.

A separation distance SL-8 from the second-first removal surface RMAS2-1 to the boundary line between the one side (left side in FIG. 8) of the reinforcement member 600 in the first direction D1 and the substrate SUB may be shorter than a separation distance SL-9 from the second-third removal surface RMAS2-3 to the boundary line between the one side (left side in FIG. 8) of the reinforcement member 600 in the first direction D1 and the substrate SUB. In addition, a separation distance SL-10 from the contact surface between the reinforcement member 600 and the protective member 700 to the second-second removal surface RMAS2-2 may be longer than the separation distance SL-8 from the second-first removal surface RMAS2-1 to the boundary line between the one side (left side in FIG. 8) of the reinforcement member 600 in the first direction D1 and the substrate SUB. The separation distance SL-10 from the contact surface between the reinforcement member 600 and the protective member 700 to the second-second removal surface RMAS2-2 may be longer than a penetration length through which the protective member 700 penetrates along the boundary line between the reinforcement member 600 and the substrate SUB.

As described above, next to (near) the contact surface between the reinforcement member 600 and the protective member 700, since the boundary line between the one side (left side in FIG. 8) of the reinforcement member 600 in the first direction D1 and the substrate SUB is spaced apart from the protective film 1000 due to the second removal area RMA-2, the protective member 700 and the protective film 1000 do not contact each other and the protective film 1000 may be easily separated from the reinforcement member 600 even when the protective member 700 penetrates the boundary line between the reinforcement member 600 and the substrate SUB.

It should be understood, however, that the advantages and features of embodiments of the disclosure are not restricted to the one set forth herein. The above and other features of the disclosure will become more apparent to one of ordinary skill in the art to which the disclosure pertains by referencing the claims, with equivalents thereof to be included therein.

What is claimed is:

1. A display device comprising:
a display panel including a substrate and a display unit;
a circuit board connected to the substrate;
a reinforcement member disposed on the substrate and extending from the circuit board toward the display unit;
a protective member disposed on the substrate, extending from the display unit toward the circuit board and contacting the reinforcement member; and
a protective film which covers the reinforcement member and in which a removal area exposing a portion of the reinforcement member is defined,
wherein the removal area is defined next to a contact surface in which the reinforcement member and the protective member contact each other.

2. The display device of claim 1,
wherein the removal area is disposed on a boundary line between the reinforcement member and the substrate.

3. The display device of claim 2,
wherein the removal area is defined by:
a first removal surface parallel to the boundary line;
a second removal surface intersecting the boundary line; and
a third removal surface spaced apart from the first removal surface so that the boundary line is disposed between the third removal surface and the first removal surface.

4. The display device of claim 3,
wherein a separation distance from the boundary line to the first removal surface is shorter than a separation distance from the boundary line to the third removal surface.

5. The display device of claim 3,
wherein a separation distance from the contact surface to the second removal surface is longer than a separation distance from the boundary line to the first removal surface.

6. The display device of claim 3,
wherein the protective film is extended to the outside of the substrate, and
the third removal surface is disposed outside the substrate.

7. The display device of claim 1,
wherein the width of the reinforcement member in a first direction is smaller than the width of the substrate in the first direction, and
one side and an opposite side of the reinforcement member in the first direction are disposed inside the substrate.

8. The display device of claim 7,
wherein the protective film is extended from a periphery of the one side of the reinforcement member in the first direction to the outside of the substrate, and
the removal area is disposed on a boundary line between the opposite side of the reinforcement member and the substrate.

9. The display device of claim 8,
wherein one side of the protective film in the first direction is spaced apart from a boundary line between the one side of the reinforcement member and the substrate.

10. The display device of claim 7,
wherein the protective film is extended in the first direction so that the one side and an opposite side of the protective film in the first direction are disposed outside the substrate,
the removal area is provided in plural so that a plurality of removal areas is provided,
the plurality of removal areas include a first removal area and a second removal area,
the first removal area is defined on the boundary line between the opposite side of the reinforcement member and the substrate, and
the second removal area is defined on the boundary line between the one side of the reinforcement member and the substrate.

11. The display device of claim 10,
wherein the first removal area is defined by:
a first-first removal surface parallel to the boundary line between the opposite side of the reinforcement member and the substrate;
a first-second removal surface intersecting the boundary line between the opposite side of the reinforcement member and the substrate; and
a first-third removal surface disposed spaced apart from the first-first removal surface so that the boundary line between the opposite side of the reinforcement member and the substrate is disposed between the first-third removal surface and the first-first removal surface.

12. The display device of claim 11,
wherein a separation distance from the boundary line between the opposite side of the reinforcement member and the substrate to the first-first removal surface is shorter than a separation distance from the boundary line between the opposite side of the reinforcement member and the substrate to the first-third removal surface.

13. The display device of claim 11,
wherein a separation distance from the contact surface to the first-second removal surface is longer than a separation distance from the boundary line between the opposite side of the reinforcement member and the substrate to the first-first removal surface.

14. The display device of claim 11,
wherein the first-third removal surface is disposed outside the substrate.

15. The display device of claim 10,
wherein the second removal area is defined by:
a second-first removal surface parallel to the boundary line between the one side of the reinforcement member and the substrate;
a second-second removal surface intersecting the boundary line between the one side of the reinforcement member and the substrate; and
a second-third removal surface spaced apart from the second-first removal surface so that the boundary line between the one side of the reinforcement member and the substrate is disposed between the second-third removal surface and the second-first removal surface.

16. The display device of claim 15,
wherein a separation distance from the boundary line between the one side of the reinforcement member and the substrate to the second-first removal surface is shorter than a separation distance from the boundary line between the one side of the reinforcement member and the substrate to the second-third removal surface.

17. The display device of claim 15,
wherein a separation distance from the contact surface to the second-second removal surface is longer than a separation distance between the one side of the reinforcement member and the substrate to the second-first removal surface.

18. The display device of claim 15,
wherein the second-third removal surface is disposed outside the substrate.

19. An electronic device comprising:
a display panel including a substrate and a display unit;
a circuit board connected to the substrate;
a reinforcement member disposed on the substrate and extending from the circuit board toward the display unit;
a protective member disposed on the substrate, extending from the display unit toward the circuit board and contacting the reinforcement member; and
a protective film disposed which covers the reinforcement member and in which at least one or more removal area exposing a portion of the reinforcement member is formed,
wherein the at least one or more removal area is defined at a periphery of a contact area in which the reinforcement member and the protective member contact each other.

20. The electronic device of claim 19,
wherein the at least one or more removal area is disposed on a boundary line between the reinforcement member and the substrate.
